(19) United States
(12) Patent Application Publication
(10) Pub. No.: US 2024/0113135 A1
(43) Pub. Date: Apr. 4, 2024

(54) LIGHT-EMITTING MODULE AND DISPLAY DEVICE

(71) Applicant: SHINE OPTOELECTRONICS (KUNSHAN) CO., LTD., Kunshan (CN)

(72) Inventors: Sheng ZHANG, Kunshan (CN); Lixiang LIU, Kunshan (CN); Shicheng ZHANG, Kunshan (CN); Yi HUANG, Kunshan (CN); Xiujun WANG, Kunshan (CN)

(73) Assignee: SHINE OPTOELECTRONICS (KUNSHAN) CO., LTD., Kunshan (CN)

(21) Appl. No.: 18/526,974

(22) Filed: Dec. 1, 2023

Related U.S. Application Data
(63) Continuation of application No. PCT/CN2022/114760, filed on Aug. 25, 2022.

(30) Foreign Application Priority Data
Aug. 27, 2021 (CN) 202110998521.0

(51) Int. Cl. H01L 27/12; H01L 25/16

(52) U.S. Cl. CPC H01L 27/124; H01L 25/167

(57) ABSTRACT

Disclosed are a light-emitting module and a display device. The light-emitting module includes a substrate, a first driving circuit layer and at least one first light-emitting unit group. At least one first groove is provided on a surface of the substrate. The first driving circuit layer is located on the substrate and includes at least one first signal line located in the first groove. The first light-emitting unit group is located on a side, where the first driving circuit layer is provided, of the substrate, and includes at least one first lamp bead, and the first lamp bead is connected in series on the first signal line. In the light-emitting module, the first signal line is arranged in the first groove of the substrate, which is equivalent to being embedded in the substrate.

### CROSS-REFERENCE TO RELATED APPLICATIONS

This application is a continuation of International Application No. PCT/CN2022/114760, filed on Aug. 25, 2022, which claims priority to Chinese Patent Application No. 202110998521.0, filed on Aug. 27, 2021. All of the aforementioned applications are incorporated herein by reference in their entireties.

### TECHNICAL FIELD

The present disclosure relates to the technical field of backlight display, in particular to a light-emitting module and a display device.

### BACKGROUND

Mini submillimeter light-emitting diode (LED) backlight display technology is a new display technology that is different from traditional liquid crystal display (LCD) and organic light-emitting diode (OLED) display. Compared with the latter two, a Mini LED backlight panel has higher color contrast, brightness, color gamut, longer lifespan and thinner thickness, which is a key area for the development of the panel industry in recent years and has broad prospects. However, the present Mini LED backlight panels are limited to their own structural design, and circuit lines used to drive Mini LED will protrude from a substrate. During the production and application process, the circuit lines may be damaged by friction, collision, etc., resulting in breakage of the circuit lines, so that there are malfunctions of the Mini LED backlight panels.

### SUMMARY

In view of this, the present disclosure provides a light-emitting module and a display device, in which a groove is provided in a substrate of the light-emitting module to accommodate a signal line in a driving circuit layer, so that the signal line will not be damaged due to exposure outside the substrate, such as abrasion, and an arrangements of the signal line will not increase a design thickness of the light-emitting module, which is conducive to a light and thin design of the light-emitting module.

The first aspect of the present disclosure provides a light-emitting module, which includes a substrate, a first driving circuit layer and at least one first light-emitting unit group. At least one first groove is provided on a surface of the substrate. The first driving circuit layer is located on the substrate and includes at least one first signal line located in the first groove. The first light-emitting unit group is located on a side, where the first driving circuit layer is provided, of the substrate, and includes at least one first lamp bead, and the first lamp bead is connected in series on the first signal line.

In the above technical solution, the first signal line is embedded in the first groove of the substrate, so that the first signal line will not be damaged due to exposure outside of the substrate, such as abrasion, and the arrangement of the first signal line will not increase the design thickness of the light-emitting module, which is conducive to the light and thin design of the light-emitting module.

In a specific embodiment of the first aspect of the present disclosure, the substrate further includes an underlying layer and a first structural layer underlying layer. The first structural layer is located on one side of the underlying layer, and the first groove is formed in the first structural layer and located on a side, away from the underlying layer, of the first structural layer.

In a specific embodiment of the first aspect of the present disclosure, the first structural layer includes a plurality of first sub-structural layers stacked together, each of the first sub-structural layers is provided with a first sub-groove. The first signal line includes a plurality of first sub-signal lines respectively located in the first sub-groove, and a first through hole is provided in the first sub-structure layer, so that the plurality of first sub-signal lines are connected through the first through hole, such as in series or in parallel.

In the above technical solution, by disposing the first sub-structural layers, the first signal line is configured to be composed of first sub-signal lines connected to each other and located in different layers, such that the arrangement space of the first signal line is further increased, and the area occupied by the first signal line in the lateral direction of the substrate is reduced, which thereby further reduces the resistance of the first signal line, and reduces the voltage drop generated on the first signal line when driving the first lamp bead to emit light.

In a specific embodiment of the first aspect of the present disclosure, the first groove includes a plurality of first groove segments arranged at intervals, and the light-emitting module further includes a plurality of first connecting parts. The first connecting part is located on the first structural layer and between adjacent first groove segments, each of the first connecting parts includes a first part and a second part respectively connected to the first signal line in the adjacent first groove segments. The first part and the second part are spaced apart from each other, and the first lamp bead is connected between the first part and the second part.

In a specific embodiment of the first aspect of the present disclosure, the first groove segments are divided into first type groove segments and second type groove segments, a length of the first type groove segment is shorter than a length of the second type groove segment, and a plurality of the first type groove segments are arranged in an array so that the first type groove segments of each row of the array form a first groove group, one second type groove segment is arranged between adjacent first groove groups, and two terminals of the second type groove segment are respectively connected to terminals of the adjacent first groove groups through the first connecting part.

In another specific embodiment of the first aspect of the present disclosure, the first groove segments are arranged in an array so that the first type groove segments of each row of the array form a first groove group, and two terminals of the first groove group are respectively connected to terminals of the adjacent first groove groups through the first connecting part.

In another specific embodiment of the first aspect of the present disclosure, the light-emitting module further includes a second driving circuit layer, the second driving circuit layer is located on a side, away from the first driving circuit layer, of the substrate, and the second driving circuit layer includes at least one second signal line. The substrate is provided with at least one second through hole, and the first signal line and the second signal line are connected through the second through hole, such as in series or in parallel.

In the above technical solution, the second signal line connected to the first signal line is provided on the side, away from the first lamp bead, of the substrate, and there is no need to arrange the circuit lines for driving the first lamp bead on the side of the substrate, which thereby reduces the area occupied by the circuit lines on the side, where the lamp bead is provided, of the substrate; in addition, in a case where the connection is in parallel, then the first signal line and the second signal line are connected in parallel, compared with setting the first signal line alone, the overall resistance value is reduced. In a case where the first driving circuit layer and the second driving circuit layer are driven to make the first lamp beads emit light, the voltage loss is reduced, which thereby reduces the brightness difference between the first lamp beads connected in series, so as to improve the uniformity of light emitted by the entire light-emitting module.

In a specific embodiment of the first aspect of the present disclosure, the substrate further includes a second structural layer. The second structural layer is located on a side, away from the first structural layer, of the underlying layer. At least one second groove is provided on a surface, away from the underlying layer, of the second structural layer, and the second signal line is located in the second groove.

In the above solution, the second signal line is embedded in the second groove of the substrate, so that the second signal line will not be damaged due to being exposed to the outside of the substrate, such as abrasion, and the arrangement of the second signal line will not increase the design thickness of the light-emitting module, which is conducive to the light and thin design of the light-emitting module.

In a specific embodiment of the first aspect of the present disclosure, the second structural layer includes a plurality of second sub-structural layers stacked together, each of the second sub-structural layers is provided with a second sub-groove. The second signal line includes a plurality of second sub-signal lines respectively located in the second sub-groove, and a third through hole is provided in the second sub-structure layer, so that the plurality of second sub-signal lines are connected through the third through hole, such as in series or in parallel.

In the above technical solution, by disposing multiple second sub-structural layers, the second signal line is configured to be composed of second sub-signal lines connected to each other and located in different layers, such that the arrangement space of the second signal line is further increased, and the occupied area of the second signal line in the lateral direction of the substrate is reduced, which thereby further reduces the resistance of the second signal line, and reduces the voltage drop generated on the second signal line when driving the second lamp bead to emit light.

In a specific embodiment of the first aspect of the present disclosure, the light-emitting module further includes at least one second light-emitting unit group, the second light-emitting unit group is located on a side, where the second driving circuit layer is provided, of the substrate, and includes at least one second lamp bead connected in series on the second signal line.

In the above technical solution, lamp beads can be arranged on both sides of the light-emitting module, so as to increase the arrangement density of the lamp beads and improve the overall brightness of the light-emitting module.

In a specific embodiment of the first aspect of the present disclosure, the second groove includes a plurality of second groove segments arranged at intervals, and the light-emitting module further includes a plurality of second connecting parts. The second connecting part is located on the second structural layer and between adjacent second groove segments, each of the second connecting parts includes a third part and a fourth part respectively connected to the second signal line in the adjacent second groove segments. The third part and the fourth part are spaced apart from each other, and the second lamp bead is connected between the third part and the fourth part.

In a specific embodiment of the first aspect of the present disclosure, the second groove segments are divided into third type groove segments and fourth type groove segments, a length of the third type groove segment is shorter than a length of the fourth type groove segment, and a plurality of the third type groove segments are arranged in an array so that the third type groove segments of each row of the array form a second groove group, one fourth type groove segment is arranged between adjacent second groove groups, and two terminals of the fourth groove segment are respectively connected to terminals of the adjacent second groove groups through the second connecting part.

In a specific embodiment of the first aspect of the present disclosure, the second groove segments are arranged in an array so that the second type groove segments of each row of the array form a second groove group, and two terminals of the second groove group are respectively connected to terminals of the adjacent second groove groups through the second connecting part.

In a specific embodiment of the first aspect of the present disclosure, an orthographic projection, on a plane where the substrate is located, of the second lamp bead coincides with an orthographic projection, on a plane where the substrate is located, of the first lamp bead.

In a specific embodiment of the first aspect of the present disclosure, the orthographic projection, on the plane where the substrate is located, of the second lamp bead is located between gaps of the orthographic projection, on the plane where the substrate is located, of the first lamp bead.

In the above technical solution, the light of the second lamp bead can be emitted through the gap of the first lamp beads, so that the distribution of light emitted by the light-emitting module is uniform.

In a specific embodiment of the first aspect of the present disclosure, the substrate is a transparent substrate, and the first groove and the second groove are grid-like grooves so that the first signal line and the second signal line have a grid-like structure.

In the above technical solution, designing the first signal line and the second signal line as a grid structure can make the first signal line and the second signal line appear transparent as a whole, which thereby increases the light transmittance of the substrate to improve the brightness of the emitting light.

A second aspect of the present disclosure provides a display device, which includes the light-emitting module in the first aspect mentioned above.

In a specific embodiment of the second aspect of the present disclosure, the first lamp bead is configured to emit colored light.

In a specific embodiment of the second aspect of the present disclosure, the display device further includes a light homogenizing plate and a display layer overlapped with the a light homogenizing plate. The light-emitting module is configured such that the emitted light enters the display layer after passing through the light homogenizing plate.

### BRIEF DESCRIPTION OF DRAWINGS

FIG. 1 is a partial structural schematic diagram of a light-emitting module according to an embodiment of the present disclosure.

FIG. 2 is a partial structural schematic diagram of another light-emitting module according to an embodiment of the present disclosure.

FIG. 3 is a partial structural schematic diagram of another light-emitting module according to an embodiment of the present disclosure.

FIG. 4A is a planar structural schematic of a light-emitting module according to an embodiment of the present disclosure.

FIG. 4B is an enlarged structural schematic diagram of the first connecting portion and the first lamp bead in the light-emitting module shown in FIG. 4A.

FIG. 4C is a cross-sectional view of the first connecting portion and the first lamp bead shown in FIG. 4B.

FIG. 4D is an actual schematic diagram of the first connecting portion and the first groove shown in FIG. 4B.

FIG. 4E is an enlarged schematic view of a region S shown in FIG. 4A.

FIG. 5 is a schematic plan view of a light-emitting module according to an embodiment of the present disclosure.

FIG. 6 is a partial structural schematic diagram of another light-emitting module according to an embodiment of the present disclosure.

FIG. 7 is a partial structural schematic diagram of another light-emitting module according to an embodiment of the present disclosure.

FIG. 8 is a schematic structural diagram of a display device according to an embodiment of the present disclosure.

### DETAILED DESCRIPTION OF THE EMBODIMENTS

The technical solutions in the embodiments of the present disclosure will be clearly and completely described with reference to the accompanying drawings in the embodiments of the present disclosure in the following. Obviously, the described embodiments are only some of the embodiments of the present disclosure, not all of them. Based on the embodiments in the present disclosure, all other embodiments obtained by persons of ordinary skill in the art without making creative efforts belong to the protection scope of the present disclosure.

The present disclosure provides a light-emitting module and a display device. A groove is provided in a substrate of the light-emitting module for accommodating a signal line in a driving circuit layer, so that the signal line will not be damaged due to exposure to the outside of the substrate, such as abrasion, and the arrangement of the signal line will not increase a design thickness of the light-emitting module, which is conducive to a light and thin design of the light-emitting module. The signal lines can be used to transmit signals, connect power, and so on.

At least one embodiment of the present disclosure provides the light-emitting module, which includes the substrate, the first driving circuit layer and at least one first light-emitting unit group. At least one first groove is provided on the surface of the substrate. The first driving circuit layer is located on the substrate and includes at least one first signal line located in the first groove. The first light-emitting unit group is located on a side, where the first driving circuit layer is provided, of the substrate, and includes at least one first lamp bead, and the first lamp bead is connected in series with the first signal line. The first signal line is embedded in the first groove of the substrate, so that the first signal line will not be damaged due to exposure to the outside of the substrate, such as abrasion, and the arrangement of the first signal line will not increase the design thickness of the light-emitting module, which is conducive to the light-weight design of the light-emitting module.

Hereinafter, the light-emitting module and the display device according to the at least one embodiment of the present disclosure will be described with reference to the accompanying drawings. In addition, in these embodiments, a spatial Cartesian coordinate system is established based on a plane where the substrate is located (In the case where the substrate includes the underlying layer, the plane is equivalent to a plane where the underlying layer is located), so as to describe the position of each structure in the light-emitting module and the display device. In the spatial Cartesian coordinate system, the X-axis and Y-axis are parallel to the plane where the substrate is located, and the plane of the Z-axis is perpendicular to the plane where the substrate is located.

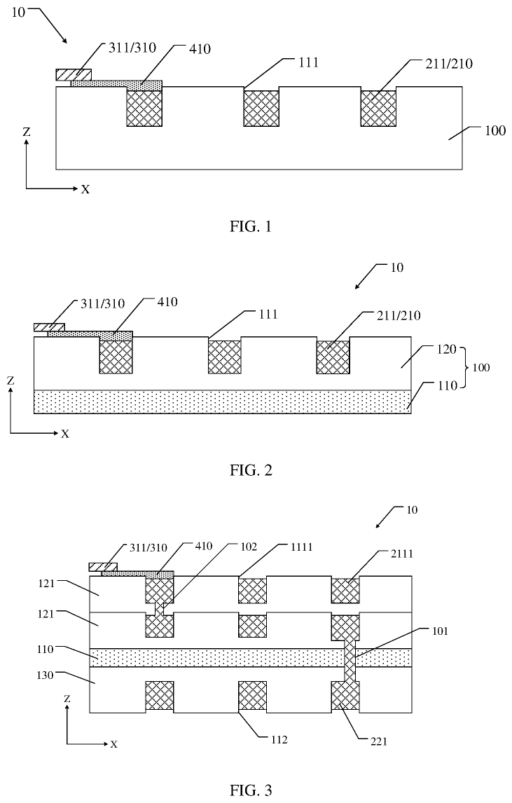

As shown in FIG. 1, in the light-emitting module 10, the first driving circuit layer 210 is located on one side of the substrate 100, at least one first light-emitting unit group 310 is provided on the first driving circuit layer 210, the first light-emitting unit group 310 includes a first lamp bead 311, and the first driving circuit layer 210 includes a first signal line 211. A first groove 111 is provided on the surface of the substrate 100, and the first signal line 211 is located in the first groove 111. For example, the first signal line 211 may be configured to have one-to-one correlation with the first light-emitting unit group 310. For example, in a case where each first light-emitting unit group 310 includes a plurality of first light beads 311, the plurality of first light beads 311 of the first light-emitting unit group 310 may be connected in series to a corresponding first signal line 211. Since the first signal line 211 is embedded in the first groove 111, it will not be damaged by scratches or the like. In addition, since the substrate 100 is provided with the first groove 111, the average thickness of the substrate 100 is reduced, which makes the substrate 100 easier to bend, that is, the light-emitting module has a stronger bending ability, which is more conducive to the application of the light-emitting module in the field of curved or flexible displays.

For example, in some embodiments of the present disclosure, in the preparation process of the light-emitting module, after the substrate 100 is provided, the first groove 111 can be formed on the surface of the substrate 100 by means of imprinting (for example, hot embossing), etching (for example, photolithography), and the like. For example, in some other embodiments of the present disclosure, the substrate 100 having the first groove 111 may be directly formed by using methods like molding.

In the light-emitting module provided by at least one embodiment of the present disclosure, the substrate further includes an underlying layer and a first structural layer. The first structural layer is located on one side of the underlying layer, and the first groove is formed in the first structural layer and located on the side, away from the underlying layer, of the first structural layer. Exemplarily, as shown in FIG. 2, the substrate 100 includes the underlying layer 110 and the first structural layer 120 above the underlying layer 110. The first structural layer 120 is used to form the first groove 111. The underlying layer 110 can be used as the base of the entire substrate. Compared with the first structural layer 120, the underlying layer 110 can have greater strength (for example, tensile, compressive, etc.) to provide support, and the underlying layer 110 can be designed to use a flexible base material with a smaller thickness, so that it has good bending performance. Exemplarily, the first structural layer 120 is UV resin. During the preparation process, the UV resin can be coated on the underlying layer 110, and the UV resin can be embossed and cured using a corresponding mold, and then the first groove 111 is formed after demoulding, and then fill the first groove 111 with a conductive material to form the first signal line 211. Similarly, UV resin is coated on the other side of the underlying layer 110, and the UV resin is embossed and cured using a corresponding mold, and then a second groove 112 is formed after demoulding, and then the second groove 112 is filled with the conductive material to form a second signal line 221. Then, a plurality of first through holes 101 are formed by laser drilling at appropriate positions (selected according to process requirements), and the conductive material is filled in the first through holes 101, and the conductive material in the first through holes 101 are respectively in contact with the conductive material in the first groove 111 and the second groove 112 to realize electrical connection of the first signal line 211 and the second signal line 221. For example, in at least one embodiment of the present disclosure, the first groove 111 is in a grid shape, the second groove 112 is in a grid shape, and the diameter of the first through holes 101 is respectively larger than the grid width of the first groove 111 and the second groove 112, so as to ensure the connection between the first through hole 101 and the first groove 111 and ensure the connection between the first through hole 101 and the second groove 112.

In the light-emitting module provided by at least one embodiment of the present disclosure, the first structural layer includes a plurality of first sub-structural layers stacked together, and each first sub-structural layer is provided with a first sub-groove. The first signal line includes a plurality of first sub-signal lines respectively located in the first sub-groove, and the first through hole is arranged in the first sub-structural layer, so that the plurality of first sub-signal lines are connected through the first through hole. By arranging a plurality of first sub-structural layers, the first signal line is configured to be composed of first sub-signal lines connected to each other and located in different layers, which thereby further increases the arrangement space of the first signal line, so as to reduce the occupied area of the first signal line in the lateral direction of the substrate, which further reduces the resistance of the first signal line, and reduces the voltage drop generated on the first signal line when the first lamp bead is driven to emit light. Exemplarily, as shown in FIG. 3, the first structural layer of the substrate includes two first sub-structural layers 121 stacked on the underlying layer 110, and the surface, facing away from the underlying layer 110, of each sub-structural layer 121 is formed with the first sub-groove 1111, the first sub-signal line 2111 of the first signal line is filled in the first sub-groove 1111. In this way, the first groove is divided into first sub-grooves 1111 located in two layers, and the first signal line is also divided into first sub-signal lines 2111 located in two layers. The first sub-signal lines 2111 in the two layers can be connected together through the first through hole 102 in the first sub-structural layer 121. For example, a plurality of first through holes 102 can be provided, so that multi-point connections can be realized between the first sub-signal lines 2111 of the two layers.

For example, in the embodiment of the present disclosure, the thickness of the first sub-signal line 2111 in FIG. 3 is equal to the thickness of the first signal line 211 in FIG. 1 or FIG. 2, or the sum of the thicknesses of the first sub-signal lines 2111 of the first sub-structural layer 121 in different layers is greater than the thickness of the first signal line 211 in FIG. 1 or FIG. 2, in this case, the total resistance of the first signal line in FIG. 3 would be smaller than the total resistance of the first signal line 211 in FIG. 1 or FIG. 2.

In the embodiment of the present disclosure, in the case where the first groove is provided on the substrate, there is no restriction on the extended shape of the first groove, and it can be designed according to actual process requirements. Hereinafter, several design structures of the first groove and the structure of the corresponding light-emitting module will be described with reference to the accompanying drawings.

For example, in some embodiments of the present disclosure, in the light-emitting module provided, the first groove (or the first sub-groove) corresponding to each first signal line may be a continuous groove structure, that is, the first signal line (or the first sub-signal line) is a continuous and uninterrupted signal line.

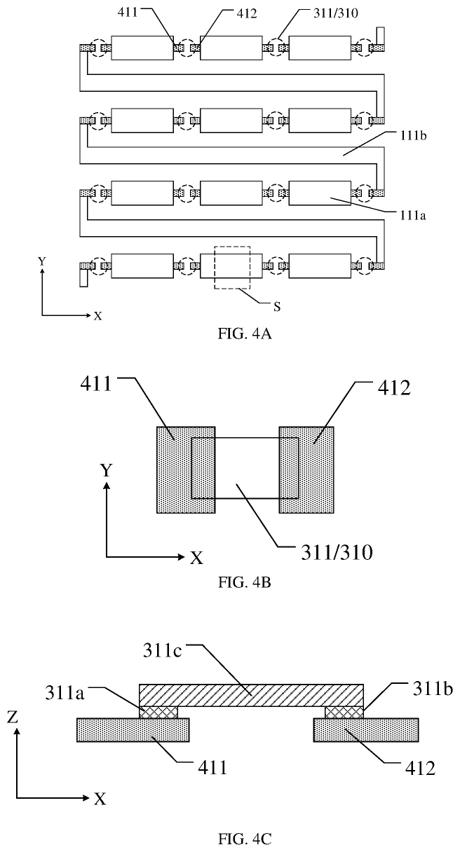

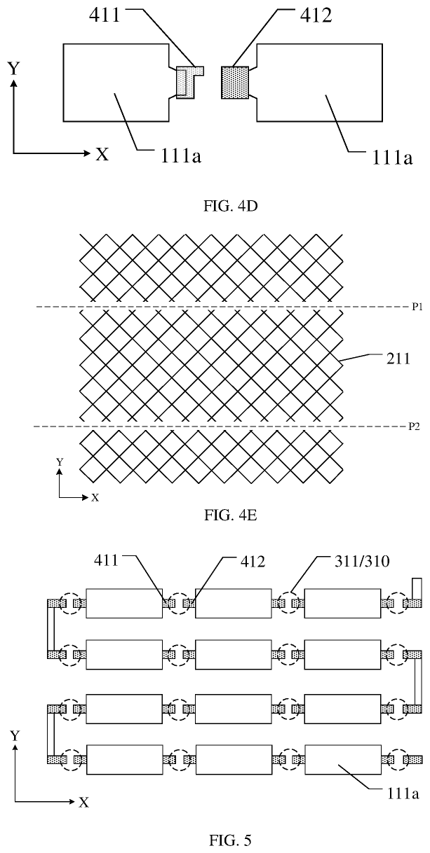

For example, in the light-emitting module provided in other embodiments of the present disclosure, the first groove includes a plurality of first groove segments arranged with spacing intervals, and the light-emitting module further includes a plurality of first connecting parts. The first connecting parts are located on the first structural layer and between adjacent first groove segments, and each first connecting part includes a first part and a second part, respectively connected with the first signal line in the adjacent first groove segment. The first part and the second part are spaced apart from each other, and the first lamp bead is connected between the first part and the second part. Because the first signal line is embedded in the first groove, when the first lamp bead is installed, it is difficult for the first lamp bead to be in direct contact with the first signal line, in these embodiments, drawing out the first signal line through the first part and the second part of the first connecting part, so that the first signal line can be connected to the first lamp bead by means of the first connecting part. Exemplarily, as shown in FIG. 2 and FIG. 4A to FIG. 4C, the first groove 111 is configured to be formed by a plurality of first groove segments arranged with spacing intervals, that is, the first groove 111 is broken into a plurality of grooves, each groove is the first groove segment, the first part 411 and the second part 412 of the first connecting part 410 are respectively connected to different first groove segments, and each first lamp bead 311 includes pins 311a, 311b and a body part 311c (can be energized to emit light), the pin 311a is connected to the first part 411, and the pin 311b is connected to the second part 412, so that the first lamp bead 311 is connected in series on the first signal line. For example, the first connecting part 410 can be designed such that a portion of the first part 411 and the second part 412 covers a portion of the first groove 111, thereby ensuring that the first part 411 and the second part 412 are connected to the first signal line in the first groove 111.

It is to be noted that, in the disclosed embodiment, the first part 411 and the second part 412 of the first connecting part 410 can be designed according to a specific type of the first lamp bead. For instance, in the case of conventional LED lamp beads, the first part 411 and the second part 412 of the first connecting part 410 can be designed as the structure illustrated in FIG. 4, that is, the first part 411 is designed to be similar to an “L” shape, and the second part 412 is designed to be similar to a rectangular shape.

In the light-emitting module provided by some embodiments of the present disclosure, the first groove segments are divided into a first type groove segment and a second type groove segment. The length of the first type groove segment is shorter than the length of the second type groove segment. A plurality of first type groove segments are arranged in an array so that each row of the array of first type groove segments forms a first groove group, the second type groove segment is arranged between adjacent first groove groups, and the two terminals of the second type groove segment are respectively connected to the terminals of the adjacent first groove groups through the first connecting part. As illustrated in FIG. 4A, the first groove segments of the first groove have varying lengths, the first groove segments are divided into the first type groove segment 111a and the second type groove segment 111b, the length of the first type groove segment 111a is shorter than the length of the second type groove segment 111b, and the array of the first type groove segment 111a is arranged in 4 rows (the row direction is parallel to the X-axis direction) and 3 columns (the column direction is parallel to the Y-axis direction), single first type groove segments 111a in each row are formed as the first groove group, thereby forming 4 first groove groups, the second type groove segment 111b is arranged between the adjacent first groove groups, and adjacent first groove groups are connected together through the second type groove segments 111b, that is, a plurality of first groove groups (the first type groove segments 111a) and a plurality of second type groove segments 111b are arranged alternately and connected terminal to terminal to form a multi-level “S” shape.

In the light-emitting module provided in other embodiments of the present disclosure, the first groove segments are arranged in an array such that the first groove segments of each row of the array form the first groove group, and the two terminals of the first groove group are connected with the terminals of the adjacent first groove group through the first connecting part, respectively. Exemplarily, as shown in FIG. 5, the first groove segments of the first groove are all first type groove segments 111a, and the array of the first type groove segments 111a is arranged in 4 rows (the row direction is parallel to the X-axis direction) and 3 columns (the column direction is parallel to the Y-axis direction), single first-type groove segments 111a in each row are formed into the first groove group, thereby forming 4 first groove groups, and the 4 first groove groups are connected terminal to terminal, that is, a plurality of first groove groups (the first type groove segments 111a therein) are connected terminal to terminal to form a multi-level “S” shape.

In at least one embodiment of the present disclosure, the light-emitting module further includes a second driving circuit layer, the second driving circuit layer is located on a side, away from the first driving circuit layer, of the substrate, and includes at least one second signal line. The substrate is provided with at least one second through hole, and the first signal line and the second signal line are connected through the second through hole, for example, connected in series or in parallel. The second signal line connected to the first signal line is arranged on the side, away from the first lamp bead, of the substrate, and the circuit for driving the first lamp bead does not need to be arranged on the side of the substrate, thereby reducing the area occupied by the circuit on the side of the substrate where the lamp bead is arranged. In addition, in a case where the connection is in parallel, then the first signal line and the second signal line are connected together, compared with setting the first signal line alone, the overall resistance becomes smaller, and when driving the first driving circuit layer and the second driving circuit layer to make the first lamp bead emit light, the voltage loss is reduced, thereby reducing the brightness difference between the first lamp beads connected in series, so as to improve the uniformity of light emitted by the entire light-emitting module.

Exemplarily, as shown in FIG. 2 or FIG. 3, in the light-emitting module 10, the first driving circuit layer 210 and the second driving circuit layer 220 are located on both sides of the substrate, and the second driving circuit layer 220 includes the second signal line 221. The substrate 100 is provided with the second through hole 101, and the first signal line 211 and the second signal line 221 are connected through the second through hole 101.

It should be noted that FIG. 2 and FIG. 3 are cross-sectional views illustrating only a partial structure of the light-emitting module 10. In the entire light-emitting module 10, a plurality of second through holes 101 are provided in the substrate 100, so that each first signal line 211 and the corresponding second signal line 221 can be connected at multiple points, that is, each first signal line 211 and the corresponding second signal line 221 are connected in parallel.

It should be noted that, in the embodiments of the present disclosure, the width of the second through hole may be smaller than, equal to, or larger than the width of the first groove where the second through is located, and is not limited to the arrangement shown in FIG. 2 and FIG. 3. For example, the size of the part, in the area where the second through hole is provided, of the first groove is larger than the size of the part of the first groove in other areas, so that the second through hole has a larger width, that is, in the position of the second through hole, the part, located in the groove, of the first signal line, and the conductive material filled in the second through hole (which can be integrally formed with the first signal line) form a structure similar to a contact pad, by having a relatively large design area, to ensure the alignment between the first signal line, the conductive material filled in the second through hole, and the second signal line, thereby ensuring the connection between the first signal line and the second signal line.

For example, in some embodiments of the present disclosure, in the case where the first groove is formed by photolithography, the first groove and the second through hole 101 can be formed in the same photolithography process, thereby reducing the preparation process of the light-emitting module. For example, when forming the first groove 111 on the substrate 100, photoresist may be deposited on the substrate 100, and then a two-tone mask is provided, that is, the mask includes a first light-transmitting region and a second light-transmitting region and a light-shielding region, the light transmittance of the first light-transmitting region is greater than the light transmittance of the second light-transmitting region, the first light-transmitting region corresponds to the position of the second through hole 101 to be formed, and the second light-transmitting region corresponds to the position of the first groove 111 to be formed (except the position where the second through hole 101 is located); then the photoresist is exposed and developed, and the part, corresponding to the position of the second through hole 101 to be formed, of the photoresist is removed, the part, corresponding to the position of the first groove 111 to be formed, of the photoresist is thinned; then the substrate 100 is etched with the remaining photoresist as a mask, and the depth of the formed second through hole 101 will be greater than the depth of the first groove 111.

In some embodiments of the present disclosure, the second driving circuit layer can be further provided in a manner referring to the first driving circuit. For example, the second signal line of the second driving circuit layer can be arranged in the groove, and the second signal line can also be arranged to be formed by connecting a plurality of sub-signal lines, the second signal line and the shape of the groove that defines the second signal line can refer to the above-mentioned first signal line and the shape of the first groove that defines the first signal line. Next, the structure of the light-emitting module in these embodiments will be described.

In the light-emitting module provided by at least one embodiment of the present disclosure, the substrate further includes a second structural layer. The second structural layer is located on a side, away from the first structural layer, of the underlying layer, at least one second groove is arranged on the surface, away from the underlying layer, of the second structure, and the second signal line is located in the second groove. The second signal line is embedded in the second groove of the substrate, so that the second signal line will not be damaged due to exposure outside of the substrate, such as abrasion, and the arrangement of the second signal line will not increase the design thickness of the light-emitting module, which is conducive to the light and thin design of the light-emitting module. Exemplarily, referring to FIG. 2 or FIG. 3 again, the second structural layer 130 is provided on the surface, away from the first driving circuit layer 210, of the underlying layer 100, and a second groove 112 is provided on the surface, away from the underlying layer 110, of the second structural layer 130, the second signal line 221 is located in the second groove 112.

In the light-emitting module provided in at least one embodiment of the present disclosure, the second structural layer includes a plurality of second sub-structure layers stacked together, and each second sub-structural layer is provided with a second sub-groove. The second signal line includes a plurality of second sub-signal lines respectively located in the second sub-grooves, and a third through hole is arranged in the second sub-structural layer, so that the plurality of second sub-signal lines are connected through the third through hole. By arranging a plurality of second sub-structural layers, the second signal line is configured to be composed of second sub-signal lines which are connected to each other and located in different layers, which thereby further increases the layout space of the second signal line, so as to reduce the occupied area, in the lateral direction of the substrate, of the second signal lines, which further reduces the resistance of the second signal line, and reduces the voltage drop generated on the second signal line in a case where the second lamp bead is driven to emit light. In this embodiment, the arrangement of the second structural layer and the second signal line may be the arrangement of the first structural layer and the first signal line in the above embodiment shown in FIG. 3, and details are not repeated here.

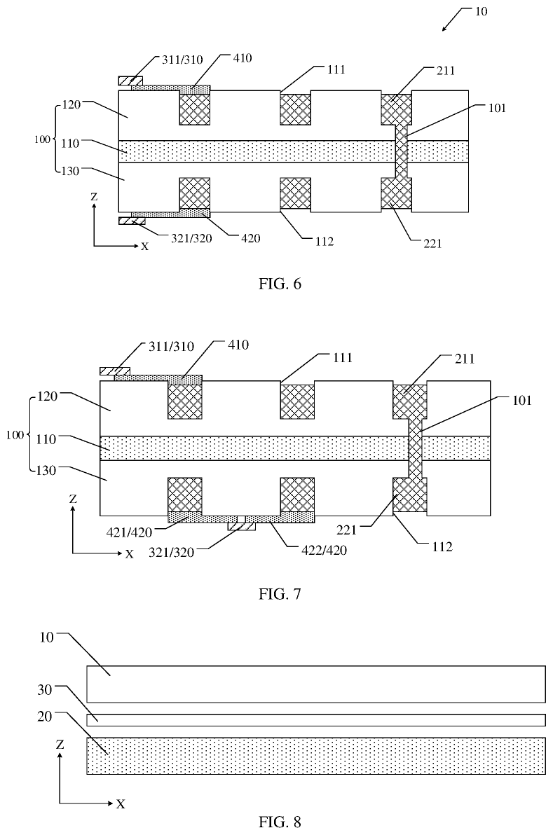

In the light-emitting module provided in at least one embodiment of the present disclosure, the light-emitting module further includes at least one second light-emitting unit group, the second light-emitting unit group is located on the side, where the second driving circuit layer is provided, of the substrate, and includes at least one second lamp bead connected in series on the second signal line. In this way, lamp beads can be arranged on both sides of the light-emitting module, so as to increase the arrangement density of the lamp beads and improve the overall brightness of the light-emitting module. Exemplarily, as shown in FIG. 6, the second light-emitting unit group 320 is provided on the side, away from the underlying layer 110, of the second structural layer 130, and the second light-emitting unit group includes a plurality of second lamp beads 321.

In the light-emitting module provided in at least one embodiment of the present disclosure, the second groove includes a plurality of second groove segments arranged at intervals, and the light-emitting module further includes a plurality of second connecting part. The second connecting part is located on the second structural layer and between adjacent second groove segments, and each second connecting part includes a third part and a fourth part respectively connected to the second signal line in the adjacent second groove segment. The third part and the fourth part are spaced apart from each other, and the second lamp bead is connected between the third part and the fourth part. Exemplarily, as shown in FIG. 6 or FIG. 7, the second groove 112 is configured to be formed by a plurality of second groove segments arranged at intervals, that is, the second groove 112 is broken into a plurality of grooves, and each groove is a first groove segment, the third part 421 and the fourth part 422 of the second connecting part 420 are respectively connected to different first groove segments, and each second lamp bead 321 (or a part used to connect with an external circuit) is located between the third part 421 and the fourth part 422. In this embodiment, the arrangement of the second lamp bead 321 and the second connecting part 420 can refer to the relevant descriptions about the first lamp bead and the first connecting part in the foregoing embodiments, and details are not repeated here.

In an embodiment of the present disclosure, the material of the underlying layer can be glass, plexiglass, PET (polyethylene terephthalate), PMMA (polymethyl methacrylate), PI (polyimide), CPI (transparent polyimide), etc., the thickness of the underlying layer can be 25250 microns. The material of the first and second structural layers can be ultraviolet curable acrylic resin or the like.

In an embodiment of the present disclosure, the first and second lamp beads may be LED lamp beads.

In an embodiment of the present disclosure, the material of the first and second connecting parts may be solderable conductive materials, such as metallic tin and the like. For example, the thickness of the first connecting part and second connecting part may be 5-20 microns.

In the light-emitting module provided by some embodiments of the present disclosure, the second groove segment is divided into a third type groove segment and a fourth type groove segment, the length of the third type groove segment is shorter than the length of the fourth type groove segment, and a plurality of third type groove segments are arranged in an array so that the third type groove segments of each row of the array form a second groove group, and the fourth type groove segment is arranged between adjacent second groove groups, and two terminals of the fourth type groove segments are respectively connected to terminals of the adjacent second groove groups through the second connection portions. In this embodiment, the arrangement of the second groove and the second groove segment therein can refer to the arrangement of the first groove and the first groove segment therein in FIG. 4A. The third type groove segment and the fourth type groove segment respectively correspond to the first type groove segment and the second type groove segment in the embodiment shown in FIG. 4A.

In the light-emitting module provided by other embodiments of the present disclosure, the second groove segments are arranged in an array so that the second groove segments of each row of the array form a second groove group, and two terminals of the second groove group are connected with terminals of the adjacent second groove group through the second connecting portion. In this embodiment, the arrangement of the second groove and the second groove segment therein can refer to the arrangement of the first groove and the first groove segment therein in FIG. 5. The third type groove segment corresponds to the first type groove segment in the embodiment shown in FIG. 5.

In the light-emitting module provided by some embodiments of the present disclosure, the orthographic projection, on the plane where the substrate is located, of the second lamp bead coincides with the orthographic projection, on the plane where the substrate is located, of the first lamp bead. Exemplarily, as shown in FIG. 6, the first lamp bead 311 and the second lamp bead 321 are overlapped. In this way, the arrangement of the second lamp bead 321 will not reduce the overall light transmittance of the light-emitting module, which is beneficial to the application of the light-emitting module in the field of transparent display.

In the light-emitting module provided by at least one embodiment of the present disclosure, the orthographic projection, on the plane of the substrate, of the second lamp bead is located between the gaps of the orthographic projection, on the plane of the substrate, of the first lamp bead. The light of the second lamp bead can be emitted through the gaps of the first lamp beads, so that the distribution of light emitted by the light-emitting module is uniform. Exemplarily, as shown in FIG. 7, the first lamp bead 311 and the second lamp bead 321 are arranged alternately, so that the direct light of the second lamp bead 321 (the light overall tends to be perpendicular to the surface where the underlying layer is located) can emit from gaps of the first lamp beads 311, reducing the amount of emitting light that is shielded by the first lamp beads 311, and correspondingly increasing the brightness of the light emitted by the light-emitting module 10.

In the light-emitting module provided by at least one embodiment of the present disclosure, the substrate is a transparent substrate. In this way, the light emitted by the second lamp bead can pass through the substrate and be used as an auxiliary light source for the first lamp bead, thereby increasing the brightness of the light emitted by the light-emitting module.

For example, both the first groove and the second groove are grid-like grooves so that the first signal line and the second signal line are both grid-like structures. For example, the grid density at the first connecting portion of the first groove is greater than the grid density of other regions, and a shape of a grid unit is triangular, polygon, honeycomb, random grid, etc., which has good electrical conductivity.

For example, in a case where the substrate is a transparent substrate, the first groove and the second groove are grid-like grooves so that the first signal line and the second signal line have a grid-like structure, in this way, the first signal line and the second signal line can be appeared transparent as a whole, so as to increase the light transmittance of the substrate and improve the brightness of emitting light.

For example, when preparing the first and second signal lines (or their included sub-signal lines), the grid structure of the entire layer can be formed first, and then the grid structure can be divided to form the first and second signal lines. For example, in a case where the first and second signal lines are formed in the groove, the groove can be designed as the grid structure, so that the first and second signal lines formed in the groove appear in a grid shape.

It should be noted that when dividing the grid structure, the first and second signal lines (or grooves for these signal lines) can be obtained only by breaking the grid lines, that is, residual grid structure is retained between the adjacent first signal lines and between the adjacent second signal lines, and the residual grid structure does not participate in the formation of components such as signal lines, thus serving as dummy region. The residual grid structure can make the overall light transmittance of the substrate uniform, thereby improving the uniformity of emitting light from the substrate.

Exemplarily, as shown in FIG. 4A and FIG. 4E, in the design process of the first signal line 211, the entire grid structure as shown in FIG. 4E can be set first, and then the grid structure is divided along the lines P1 and P2, the grid lines of the grid structure are disconnected at the lines P1 and P2, the part, located between the lines P1 and P2, of the grid structure is the first signal line 211, and the part, located outside the lines P1 and P2, of the grid structure is used as dummy part. For example, in the case that the first signal line 211 is accommodated in the first groove, as shown in FIG. 4E, the first groove is actually the same as the grid line that accommodates the grid structure, and correspondingly, the grid line of the dummy part is also accommodated by the corresponding first groove. It should be noted that the structure shown in FIG. 4E can be applied to the case where the first signal line 211 includes a plurality of first sub-signal lines. In an embodiment of the present disclosure, the cross-sectional shapes of the first and second grooves can be rectangles or inverted trapezoids. For example, in a case where the cross-sectional shape is an inverted trapezoid, the side walls of the first and second grooves are inclined (non-parallel and non-perpendicular) compared to the bottom, and the bottom of the trapezoid is located on the side, away from the underlying layer, of the top. For example, the angle between the side wall and the bottom of each one of the first and second grooves is between 90° and 120°.

In an embodiment of the present disclosure, the depth-to-width ratio of the first groove and/or the second groove (the width is a dimension of the groove along a direction perpendicular to the groove's extending direction and parallel to the surface of the underlying layer) may be greater than or equal to 2.5. The width can range from 4 to 40 microns, and the depth can range from 10 to 100 microns, such as 20 microns. In this way, by arranging the first and second signal lines in the first and second grooves, the first and second grooves have a larger depth-to-width ratio, thereby which effectively reduces production costs and improves the stability of long-term use of the lines. The depth-to-width ratio greater than or equal to 2.5 is used, and the groove depth can be greater than or equal to 20 μm, so that the impedance of the lines is very low (square resistance can reach 2-8 mΩ/□), in addition, it can be combined with the multi-layer design of the first and second through holes, so it has better electrical conductivity, which can ensure the feasibility of large-area high-density lamp bead array design. In addition, the formation of the first and second signal lines in the first and second grooves can use underlying layer-free or flexible underlying layers (for example, PET), so that the light-emitting module is transparent and flexible, so that it can be used for transparent display, such as outdoor advertising etc., the overall thickness of the light-emitting module can also be reduced, and the application range is wider.

In an embodiment of the present disclosure, the thicknesses of the first and second signal lines filled in the first and second grooves may be less than or equal to the depths of the first and second grooves. For example, the thickness of the first and second signal lines can be 18-20 microns.

In an embodiment of the present disclosure, the size of the first and second through holes may be 50-300 microns, such as 100, 150, 200, 250 microns and so on.

In an embodiments of the present disclosure, the distance between adjacent first lamp beads and/or the distance between adjacent second lamp beads can be designed according to actual process requirements, for example, it can be 200-2000 microns.

In an embodiments of the present disclosure, under the condition that the first signal line and the second signal line are ensured to be electrically conductive, no further limitation is imposed on the materials of the first signal line and the second signal line. For example, the material may be gold, silver, copper, iron, nickel, tin and other metals or metal alloys.

For example, in an embodiment of the present disclosure, a reflective layer may be provided on the side, away from the substrate, of the second lamp bead, to ensure that all the light emitted by the second lamp bead can be reflected to the first lamp bead, so as to improve the brightness of the light emitted from the light-emitting module.

For example, in an embodiment of the present disclosure, an optical film can be provided on the side, away from the substrate, of the first lamp bead, and the optical film may include a light homogenizing sheet, a diffusion sheet, etc., and the optical film can make the light distributing uniformly and the light can be straightened (converted into a linear beam, for example, the overall transmission direction of the linear beam is basically perpendicular to the surface where the substrate is located).

At least one embodiment of the present disclosure provides a display device, and the display device includes the light-emitting module in any one of the above embodiments. It should be noted that, in the display device, the light-emitting module can directly display images, or serve as a light source of a device for displaying images.

For example, in the display device provided by some embodiments of the present disclosure, the first lamp bead (or the first lamp bead and the second lamp bead) is configured to emit colored light. In these embodiments, the first lamp bead can serve as a sub-pixel of the display device, and multiple sub-pixels can be combined into a pixel unit (which can be called a large pixel or a display unit). In each pixel unit, different first lamp beads are set to emit light of different colors, so that the pixel unit can emit light of various colors, so that the display device has a color display function. For example, the light-emitting module adopts a flexible transparent substrate, and the display device formed is a transparent and flexible display device, which can be installed on transparent glass such as windows, and adapted to a shape of the glass. It is transparent when it is not powered on, and has a display function when it is powered on, which is used for displaying for curtains, advertisements, etc.

For example, in the display device provided by other embodiments of the present disclosure, the display device further includes a display layer and a light homogenizing plate. The display layer and the light-emitting module are stacked, and the light homogenizing plate is located between the light-emitting module and the display layer, so that the light emitted by the light-emitting module enters the display layer after passing through the light homogenizing plate. The display layer is a structure including pixels to have a display function. For example, the display layer can control the light emitted by the light-emitting module to achieve displaying, for example, the display layer includes a liquid crystal layer to achieve displaying. In this case, the display layer can be called a liquid crystal display panel or a liquid crystal display module, and the light-emitting module is used as a light source module of the liquid crystal display panel, and the light source module can be used as a front light source or a backlight source (backlight module); or, the display layer can also be a panel that is excited by the light emitted by the light-emitting module for displaying, for example, the display layer can be a quantum dot display panel, in which quantum dots are arranged in each pixel area of the display layer, and the light emitted by the light-emitting module is short-wavelength light, excited by the short-wavelength light, quantum dots can emit light in a specific wavelength range, and further setting different types of quantum dots can make the display layer emit light of different colors. In the following, the structure of the display device of the present disclosure will be described by taking the display layer including the liquid crystal layer as an example.

Exemplarily, as shown in FIG. 8, the light-emitting module 10 is located on the backlight side of the display layer 20, so as to serve as the backlight module of the display layer 20. For example, the display layer 20 may be the liquid crystal display layer. In these embodiments, the light-emitting module 10 is a direct type backlight module. For example, the display device further includes a light homogenizing plate 30, and the light-emitting module 10 is disposed facing the main surface of the light homogenizing plate 30 and is located on a side, away from the display layer 20, of the light homogenizing plate 30. For example, the light homogenizing plate 30 may include optical films such as a diffusion film and a prism film, so that the light emitted by the light-emitting module 10 can be uniformly dispersed and straightened. For example, the display layer 20 may specifically include a box structure composed of an array substrate and an opposite substrate, and the liquid crystal layer is packaged between the array substrate and the opposite substrate. The opposite substrate is provided with elements such as a color filter and a polarizer (optional), and the polarizer is arranged between the array substrate and the light-emitting module. In the case of including the above-mentioned structure, the design of the display layer 20 can further refer to the present relevant design of the panel-type structure (excluding the light source module structure) of the liquid crystal display, which will not be repeated here.

In the embodiments of the present disclosure, the display layer can be any panel structure that requires a backlight or a front light source (in this case, the display layer can be a reflective display layer with an additional light source), and is not limited to a liquid crystal display layer. For details, reference may be made to various present display panels requiring additional light sources, and there is no limitation here.

In the embodiments of the present disclosure, the display device may be any product or component with a display function such as a billboard, a vending machine, a television, a digital camera, a mobile phone, a watch, a tablet computer, a notebook computer, a navigator, and the like.

The above is only preferred embodiments of the application, and is not intended to limit the application. Any modifications, equivalent replacements, etc. made within the spirit and principles of the application shall be included in the protection scope of the application.

What is claimed is:

1. A light-emitting module, comprising:
a substrate, comprising at least one first groove provided on a surface of the substrate;
a first driving circuit layer, located on the substrate and comprising at least one first signal line located in the first groove; and
at least one first light-emitting unit group, located on a side, where the first driving circuit layer is provided, of the substrate, and comprising at least one first lamp bead, and the at least one first lamp bead being connected in series on the first signal line.

2. The light-emitting module according to claim 1, wherein the substrate further comprises:
an underlying layer; and
a first structural layer, located on one side of the underlying layer, wherein the first groove is formed in the first structural layer and is located on a side, away from the underlying layer, of the first structural layer.

3. The light-emitting module according to claim 2, wherein
the first structural layer comprises a plurality of first sub-structural layers stacked together, each of the plurality of first sub-structural layers is provided with a first sub-groove;
the first signal line comprises a plurality of first sub-signal lines respectively located in the first sub-groove, and a first through hole is provided in the first sub-structure layer, so that the plurality of first sub-signal lines are connected in series or in parallel through the first through hole.

4. The light-emitting module according to claim 2, wherein the first groove comprises a plurality of first groove segments arranged at intervals, and the light-emitting module further comprises:
a plurality of first connecting parts, located on the first structural layer and between adjacent first groove segments, each of the first connecting parts comprising a first part and a second part respectively connected to the first signal line in the adjacent first groove segments;
wherein, the first part and the second part are spaced apart from each other, and the first lamp bead is connected between the first part and the second part.

5. The light-emitting module according to claim 4, wherein
each of the first groove segments are divided into first type groove segment and second type groove segment, a length of the first type groove segment is shorter than a length of the second type groove segment, and a plurality of the first type groove segments are arranged in an array so that the first type groove segments of each row of the array form a first groove group, one second type groove segment is arranged between adjacent first groove groups, and two terminals of the second type groove segment are respectively connected to terminals of the first groove groups adjacent to the second type groove segment through the first connecting part; or
the first groove segments are arranged in an array so that the first type groove segments of each row of the array form a first groove group, and two terminals of the first groove group are respectively connected to terminals of the first groove groups adjacent to the first groove group through the first connecting part.

6. The light-emitting module according to claim 2, further comprising:
a second driving circuit layer, located on a side, away from the first driving circuit layer, of the substrate, and comprising at least one second signal line;
wherein, the substrate is provided with at least one second through hole, and the first signal line and the second signal line are connected through the second through hole.

7. The light-emitting module according to claim 6, wherein the substrate further comprises:
a second structural layer, located on a side, away from the first structural layer, of the underlying layer;
wherein, at least one second groove is provided on a surface, away from the underlying layer, of the second structural layer, and the second signal line is located in the second groove.

8. The light-emitting module according to claim 7, wherein
the second structural layer comprises a plurality of second sub-structural layers stacked together, each of the plurality of second sub-structural layers is provided with a second sub-groove;
the second signal line comprises a plurality of second sub-signal lines respectively located in the second sub-groove, and a third through hole is provided in the second sub-structure layer, so that the plurality of second sub-signal lines are connected in series or in parallel through the third through hole.

9. The light-emitting module according to claim 7, further comprising at least one second light-emitting unit group, wherein
the at least one second light-emitting unit group is located on a side, where the second driving circuit layer is provided, of the substrate, and each of the at least one second light-emitting unit group comprises at least one second lamp bead connected in series on the second signal line.

10. The light-emitting module according to claim 9, wherein the second groove comprises a plurality of second groove segments arranged at intervals, and the light-emitting module further comprises:
a plurality of second connecting parts, located on the second structural layer and between adjacent second groove segments, each of the second connecting parts comprises a third part and a fourth part respectively connected to the second signal line in the second groove segments adjacent to the second connecting parts;
wherein, the third part and the fourth part are spaced apart from each other, and the second lamp bead is connected between the third part and the fourth part.

11. The light-emitting module according to claim 10, wherein
the second groove segments are divided into third type groove segments and fourth type groove segments, a length of the third type groove segment is shorter than a length of the fourth type groove segment, and a plurality of the third type groove segments are arranged in an array so that the third type groove segments of each row of the array form a second groove group, one fourth type groove segment is arranged between adjacent second groove groups, and two terminals of the fourth groove segment are respectively connected to terminals of the second groove groups through the second connecting part adjacent to the fourth groove segment; or
the second groove segments are arranged in an array so that the second type groove segments of each row of the array form a second groove group, and two terminals of the second groove group are respectively connected to terminals of the adjacent second groove groups through the second connecting part.

12. The light-emitting module according to claim 9, wherein
an orthographic projection, on a plane where the substrate is located, of the second lamp bead coincides with an orthographic projection, on a plane where the substrate is located, of the first lamp bead; or
an orthographic projection, on the plane where the substrate is located, of the second lamp bead is located between gaps of orthographic projections, on the plane where the substrate is located, of the first lamp beads.

13. The light-emitting module according to claim 9, wherein
the substrate is a transparent substrate, and the first groove and the second groove are grid-like grooves so that each of the first signal line and the second signal line is a grid-like structure.

14. A display device, comprising a light-emitting module, wherein the light-emitting module comprises:
a substrate, comprising at least one first groove provided on a surface of the substrate;
a first driving circuit layer, located on the substrate and comprising at least one first signal line located in the first groove; and
at least one first light-emitting unit group, located on a side, where the first driving circuit layer is provided, of the substrate, and comprising at least one first lamp bead, and the at least one first lamp bead being connected in series on the first signal line.

15. The display device according to claim 14, wherein
the first lamp bead in the light-emitting module is configured to emit a colored light.

16. The display device according to claim 15, further comprising:
a light homogenizing plate; and
a display layer, overlapped with the light homogenizing plate;
wherein, the light-emitting module is configured such that the emitting light enters the display layer after passing through the light homogenizing plate.

17. The display device according to claim 15, wherein the substrate further comprises:
an underlying layer; and
a first structural layer, located on one side of the underlying layer, wherein the first groove is formed in the first structural layer and is located on a side, away from the underlying layer, of the first structural layer.

18. The display device according to claim 17, wherein
the first structural layer comprises a plurality of first sub-structural layers stacked together, each of the plurality of first sub-structural layers is provided with a first sub-groove;
the first signal line comprises a plurality of first sub-signal lines respectively located in the first sub-groove, and a first through hole is provided in the first sub-structure layer, so that the plurality of first sub-signal lines are connected in series or in parallel through the first through hole.

19. The display device according to claim 17, wherein the first groove comprises a plurality of first groove segments arranged at intervals, and the light-emitting module further comprises:
a plurality of first connecting parts, located on the first structural layer and between adjacent first groove segments, each of the first connecting parts comprising a first part and a second part respectively connected to the first signal line in the adjacent first groove segments;
wherein, the first part and the second part are spaced apart from each other, and the first lamp bead is connected between the first part and the second part.

20. The display device according to claim 19, wherein,
each of the first groove segments are divided into first type groove segment and second type groove segment, a length of the first type groove segment is shorter than a length of the second type groove segment, and a plurality of the first type groove segments are arranged in an array so that the first type groove segments of each row of the array form a first groove group, one second type groove segment is arranged between adjacent first groove groups, and two terminals of the second type groove segment are respectively connected to terminals of the first groove groups adjacent to the second type groove segment through the first connecting part; or
the first groove segments are arranged in an array so that the first type groove segments of each row of the array form a first groove group, and two terminals of the first groove group are respectively connected to terminals of the first groove groups adjacent to the first groove group through the first connecting part.
